(19) United States
(12) Patent Application Publication
(10) Pub. No.: US 2009/0065802 A1
(43) Pub. Date: Mar. 12, 2009

(54) SEMICONDUCTOR DEVICE AND MANUFACTURING METHOD OF THE SAME

(75) Inventor: Taro Sugizaki, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/205,224

(22) Filed: Sep. 5, 2008

(30) Foreign Application Priority Data
Sep. 7, 2007 (JP) 2007-232242

(51) Int. Cl. H01L 29/74; H01L 21/762

(52) U.S. Cl. 257/133; 438/424; 257/E21.546; 257/E29.211

(57) ABSTRACT

Disclosed herein is a semiconductor device including: an element forming region of a semiconductor substrate isolated by an element isolating region formed in the semiconductor substrate; an insulating film formed on the semiconductor substrate; an opening portion formed in the insulating film to include a region to be selectively epitaxially grown in the element forming region; and a semiconductor layer formed by selective epitaxial growth of the element forming region of the semiconductor substrate in the opening portion.

### CROSS REFERENCES TO RELATED APPLICATIONS

The present invention contains subject matter related to Japanese Patent Application JP 2007-232242 filed in the Japan Patent Office on Sep. 7, 2007, the entire contents of which being incorporated herein by reference.

### BACKGROUND OF THE INVENTION

1. Field of the Invention

The present invention relates to a semiconductor device using a thyristor as a storage element and manufacturing method of the same.

2. Description of the Related Art

A memory using a thyristor (hereinafter referred to as “T-RAM”) has been proposed in which the thyristor's turn-on and turn-off characteristics are controlled by a gate electrode implemented on the thyristor. This memory (designed specifically for SRAM) is connected in series to an access transistor. The T-RAM functions as a memory by defining the off-region of the thyristor as “0” and the on-region thereof as “1.”

A thyristor basically includes a p-type region p1, n-type region n1, p-type region p2 and n-type region n2 joined together in succession. For example, it includes four n-type and p-type silicon layers. Hereinafter, this basic structure will be written as “p1/n1/p2/n2.” T-RAM, Inc. has proposed two structures. One of them is a p1/n1/p2/n2 structure implemented vertically on a silicon substrate. The other is a p1/n1/p2/n2 structure implemented horizontally on a silicon layer using an SOI substrate. In both of the structures, high-speed operation has been made possible by providing a gate electrode having a MOS structure above p2 of the p1/n1/p2/n2 structure (refer, for example, to “A Novel High Density, Low Voltage SRAM Cell with a Vertical NDR Device” by Farid Nemati and James D. Plummer, 1998 IEEE, VLSI Technology Tech. Dig. P.66 1998, “A Novel Thyristor-based SRAM Cell (T-RAM) for High-Speed, Low-Voltage, Giga-scale Memories” by Farid Nemati and James D. Plummer, 1999 IEEE IEDM Tech., p. 283 1999, “Fully Planar 0.562 μm2 T-RAM Cell in a 130 nm SOI CMOS Logic Technology for High-Density High-Performance SRAMs” by Farid Nemati, Hyun-Jin Cho, Scott Robins, Rajesh Gupta, Marc Tarabbia, Kevin J. Yang, Dennis Hayes, Vasudevan Gopalakrishnan, 2004 IEEE IEDM Tech., p. 273 2004, and Specification of U.S. Pat. No. 6,462,359 (B1)).

Further, the applicant of the present invention and T-RAM, Inc. have proposed manufacturing methods using selective epitaxial growth techniques (refer, for example, to Specification of U.S. Pat. No. 6,888,176 (B1)).

The manufacturing method proposed by T-RAM, Inc. employs a selective epitaxial manufacturing technique similar to the elevated source/drain structure used in a CMOS manufacturing technique after forming the p1/n1/p2/n2 structure, i.e., the major functional components of the thyristor. In contrast, the manufacturing method proposed by the applicant of the present invention forms one or a plurality (e.g., p1 and n2) of the layers of the p1/n1/p2/n2 structure, i.e., the major functional components of the thyristor, using a selective epitaxial growth technique.

As a result of device scaling (90 nm node generation and beyond in particular), the active region for selective epitaxial growth has become smaller. Further, facets grow (side portions of an epitaxially grown layer are formed on inclined surfaces) during selective epitaxial growth. Therefore, an epitaxially grown film grows in the form of a four-sided pyramid or trapezoid. Therefore, the effective thickness of the epitaxial film at the edge portion of the active region becomes smaller. If this epitaxially grown layer is subjected to a silicide process, a silicide layer 116 penetrates through an epitaxially grown layer 115 into a silicon substrate 111 in the worst case, causing a short circuit as illustrated in FIG. 8A. Even if no short circuit is caused, the effective thickness of the epitaxially grown layer 115 may become smaller, resulting in deterioration of the characteristic of the same layer 115. Further, if two or more epitaxially grown layers are stacked one on top of another as are epitaxially grown layers 115-1 and 115-2 as illustrated in FIG. 8B, the epitaxially grown layer 115-2 on top is short circuited to the silicon substrate 111 or in a state close thereto.

### SUMMARY OF THE INVENTION

One of the problems to be solved is the difficulty involved in preventing a silicide layer from penetrating through an epitaxially grown layer. That is, if the components of the thyristor are formed by a selective epitaxial growth technique, an epitaxially grown film grows in the form of a four-sided pyramid or trapezoid because of the growth of facets. As a result, if this epitaxially grown film is subjected to a silicide process, a silicide layer formed by the silicide reaction penetrates through the epitaxially grown film. Another problem to be solved is the risk of short circuit between the upper epitaxially grown layer and silicon substrate when two or more epitaxially grown layers are stacked one on top of another.

It is desirable to prevent a short circuit between a silicide layer formed on top of an epitaxially grown layer and semiconductor substrate or between an epitaxially grown layer and semiconductor substrate.

A semiconductor device according to an embodiment of the present invention includes an element forming region of a semiconductor substrate isolated by an element isolating region formed in the semiconductor substrate. The semiconductor device further includes an insulating film formed on the semiconductor substrate. The semiconductor device still further includes an opening portion formed in the insulating film to include a region to be selectively epitaxially grown in the element forming region. The semiconductor device still further includes a semiconductor layer formed by selective epitaxial growth of the element forming region of the semiconductor substrate in the opening portion.

The semiconductor device according to the embodiment of the present invention is surrounded by the insulating film in which the opening portion is formed to include the region to be selectively epitaxially grown. As a result, the semiconductor layer which is formed by selective epitaxial growth of the element forming region of the semiconductor substrate in the opening portion also grows along a sidewall of the opening portion. This distances the top surface of the semiconductor layer more from the semiconductor substrate by the thickness of the same layer grown.

A semiconductor device manufacturing method according to another embodiment of the present invention includes a step of forming an element isolating region in a semiconductor substrate to isolate an element forming region. The manufacturing method further includes a step of forming an insulating film on the semiconductor substrate. The manufacturing method still further includes a step of forming an opening portion in the insulating film to include a region to be selectively epitaxially grown in the element forming region. The manufacturing method still further includes a step of forming a semiconductor layer by selective epitaxial growth of the element forming region of the semiconductor substrate in the opening portion.

In the manufacturing method according to the embodiment of the present invention, the opening portion is formed to include the region to be selectively epitaxially grown in the insulating film. Therefore, the semiconductor layer formed by selective epitaxial growth of the element forming region of the semiconductor substrate in the opening portion also grows along the sidewall of the opening portion. This distances the top surface of the semiconductor layer more from the semiconductor substrate by the thickness of the same layer grown.

In the semiconductor device according to the embodiment of the present invention, the distance is large between the top surface of the semiconductor layer and the semiconductor substrate around the same substrate. This prevents a short circuit or leakage current between a silicide layer or second semiconductor layer and the semiconductor substrate even if the silicide layer or second semiconductor layer is formed on top of the semiconductor layer. As a result, a silicide process margin improves. At the same time, short circuit between the second semiconductor layer and semiconductor substrate can be eliminated, thus enhancing the process margin and providing a stable semiconductor device with minimal variation.

In the semiconductor device manufacturing method according to the embodiments of the present invention, the distance can be increased between the top surface of the semiconductor layer and the semiconductor substrate around the same substrate. This prevents a short circuit or leakage current between a silicide layer or second semiconductor layer and the semiconductor substrate even if the silicide layer or second semiconductor layer is formed on top of the semiconductor layer. As a result, the silicide process margin improves. At the same time, elimination of a short circuit between the second semiconductor layer and semiconductor substrate provides improved process margin, thus allowing to manufacture a stable semiconductor device with minimal variation.

### BRIEF DESCRIPTION OF THE DRAWINGS

FIG. 1 is a schematic configurational sectional diagram illustrating an embodiment (first example) according to a semiconductor device of the present invention;

FIG. 2 is a schematic configurational sectional diagram illustrating a modification example of the first example;

FIG. 3 is a schematic configurational sectional diagram illustrating another embodiment (second example) according to the semiconductor device of the present invention;

FIG. 4 is a relational diagram between a leakage current and applied voltage;

FIG. 5 is a schematic configurational sectional diagram illustrating a modification example of the second example;

FIGS. 6A to 6F are sectional manufacturing process diagrams illustrating the first example of the embodiment of the present invention in which the semiconductor device and a manufacturing method of the same are applied to a thyristor RAM;

FIGS. 7A to 7F are sectional manufacturing process diagrams illustrating the second example of the embodiment of the present invention in which the semiconductor device and manufacturing method of the same are applied to the thyristor RAM; and

FIGS. 8A and 8B are schematic configurational sectional diagrams illustrating the problems with the related art.

### DETAILED DESCRIPTION OF THE PREFERRED EMBODIMENTS

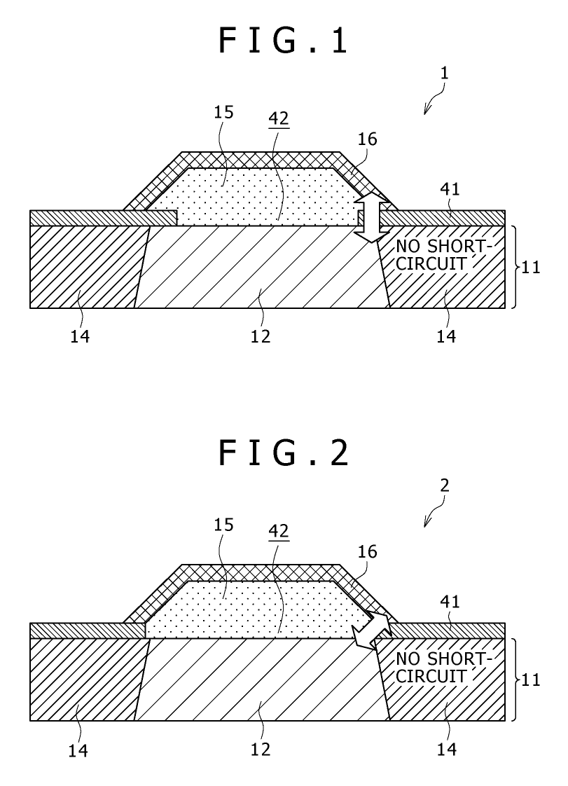

An embodiment (first example) according to the semiconductor device of the present invention will be described below with reference to the schematic configurational sectional diagram of FIG. 1.

As illustrated in FIG. 1, an element forming region 12 is isolated by an element isolating region 14 formed in a semiconductor substrate 11. The semiconductor substrate 11 includes, for example, a silicon substrate. On the other hand, the element isolating region 14 is formed by a technique such as LOCOS (Local Oxidation of Silicon), STI (Shallow Trench Isolation) or DTI (Deep Trench Isolation).

An insulating film 41 is formed on the semiconductor substrate 11. The insulating film 41 serves as a mask for selective epitaxial growth in a subsequent process. The same film 41 is formed, for example, with a silicon nitride film to a thickness of 20 nm. In the same film 41, an opening portion 42 is formed to include a region to be selectively epitaxially grown in the element forming region 12. In this example, the opening portion 42 is formed to lie over the element forming region 12. That is, the same portion 42 is formed narrower than the element forming region 12.

Then, a semiconductor layer 15 is formed by selective epitaxial growth of the element forming region 12 of the semiconductor substrate 11 in the opening portion 42. The semiconductor layer 15 should be preferably formed, for example, thicker than the insulating film 41 in the opening portion 42. Further, the semiconductor layer 15 should be preferably formed to cover part of the insulating film 41.

A silicide layer 16 is formed on the semiconductor layer 15. The silicide layer 16 is isolated from the semiconductor substrate 11 by the insulating film 41.

The semiconductor device configured as described above is surrounded by the insulating film 41 in which the opening portion 42 is formed to include the region to be selectively epitaxially grown. As a result, the semiconductor layer 15 which is formed by selective epitaxial growth of the element forming region 12 of the semiconductor substrate 11 in the opening portion 42 also grows along the sidewall of the opening portion 42. This distances the top surface of the semiconductor layer 15 more from the semiconductor substrate 11 by the thickness of the same layer 15 grown. This prevents a short circuit between the silicide layer 16 and semiconductor substrate 11 even if the silicide layer 16 is formed on top of the semiconductor layer 15. As a result, the silicide process margin improves, thus allowing to manufacture a stable semiconductor device 1 with minimal variation. Further, if the semiconductor layer 15 grows to cover the insulating film 41, a short circuit between the silicide layer 16 and semiconductor substrate 11 can be more positively prevented.

An embodiment (first example) according to the semiconductor device manufacturing method of the present invention will be described next with reference to the aforementioned FIG. 1.

For example, the semiconductor substrate 11 is made available. A silicon substrate, for example, is used as the semiconductor substrate 11. The element isolating region 14 is formed in the semiconductor substrate 11 to isolate the element forming region 12. The element isolating region 14 is formed by a technique such as LOCOS (Local Oxidation of Silicon), STI (Shallow Trench Isolation) or DTI (Deep Trench Isolation).

Next, the insulating film 41 is formed on the semiconductor substrate 11. The insulating film 41 serves as a mask for selective epitaxial growth in a subsequent process. The same film 41 is formed, for example, with a silicon nitride film to a thickness of 20 nm. Next, typical resist coating is performed, followed by the formation of an etching mask (not shown) by a lithography technique. The mask has an opening in the region to be selectively epitaxially grown of the element forming region 12. Then, the opening portion 42 is formed in the insulating film 41 on the region to be selectively epitaxially grown of the element forming region 12 by the etching process using the etching mask. Here, the region to be selectively epitaxially grown is the element forming region 12 in the opening portion 42.

Next, the semiconductor layer 15 is formed on the element forming region 12 in the opening portion 42 by selective epitaxial growth. If the semiconductor layer 15 is doped, for example, into a p-type semiconductor layer, diborane (B₂H₆) gas is used as a dopant source gas together with a silane-based gas. On the other hand, if the semiconductor layer 15 is doped into an n-type semiconductor layer, arsine (AsH₃), phosphine (PH₃) or other gas is used, for example, as a dopant source gas together with a silane-based gas. Further, the surface of the semiconductor substrate 11 may be cleaned as necessary prior to epitaxial growth with a chemical solution such as HF or hydrogen (H₂) gas.

Thereafter, the silicide layer 16 is formed on top of the semiconductor layer 15, for example, with titanium silicide, cobalt silicide or nickel silicide by a typical silicide process.

In the aforementioned manufacturing method, the opening portion 42 is formed in the insulating film 41 so as to include the region to be selectively epitaxially grown. Therefore, the semiconductor layer 15 which is formed by selective epitaxial growth of the element forming region 12 of the semiconductor substrate 11 in the opening portion 42 also grows along the sidewall of the opening portion 42. This distances the top surface of the semiconductor layer 15 more from the semiconductor substrate 11 by the thickness of the same layer 15 grown. This prevents a short circuit between the silicide layer 16 and semiconductor substrate 11 even if the silicide layer 16 is formed on top of the semiconductor layer 15. As a result, the silicide process margin improves, thus allowing to manufacture the stable semiconductor device 1 with minimal variation. Further, if the semiconductor layer 15 grows to cover the insulating film 41, a short circuit between the silicide layer 16 and semiconductor substrate 11 can be more positively prevented.

A modification example of the aforementioned first example will be described next with reference to the schematic configurational sectional diagram of FIG. 2.

As illustrated in FIG. 2, the element forming region 12 is isolated by the element isolating region 14 formed in the semiconductor substrate 11. The semiconductor substrate 11 includes, for example, a silicon substrate. On the other hand, the element isolating region 14 is formed by a technique such as LOCOS (Local Oxidation of Silicon), STI (Shallow Trench Isolation) or DTI (Deep Trench Isolation).

The insulating film 41 is formed on the semiconductor substrate 11. The insulating film 41 serves as a mask for selective epitaxial growth in a subsequent process. The same film 41 is formed, for example, with a silicon nitride film to a thickness of 20 nm. In the same film 41, the opening portion 42 is formed to include the region to be selectively epitaxially grown in the element forming region 12. In this example, the opening portion 42 is formed to lie over the element isolating region 14. That is, the same portion 42 is formed wider than the element forming region 12.

Then, the semiconductor layer 15 is formed by selective epitaxial growth of the element forming region 12 of the semiconductor substrate 11 in the opening portion 42. The semiconductor layer 15 should be preferably formed, for example, thicker than the insulating film 41 in the opening portion 42. Further, the semiconductor layer 15 may be formed to cover part of the insulating film 41.

The silicide layer 16 is formed on the semiconductor layer 15. The silicide layer 16 is isolated from the semiconductor substrate 11 by the insulating film 41.

The semiconductor device configured as described above is surrounded by the insulating film 41 in which the opening portion 42 is formed to include the region to be selectively epitaxially grown. Further, the epitaxial growth also takes place horizontally. Therefore, the semiconductor layer 15 which is formed by selective epitaxial growth of the element forming region 12 of the semiconductor substrate 11 in the opening portion 42 also grows in contact with the sidewall of the opening portion 42. This distances the top surface of the semiconductor layer 15 more from the semiconductor substrate 11 by the thickness of the same layer 15 grown. This prevents a short circuit between the silicide layer 16 and semiconductor substrate 11 even if the silicide layer 16 is formed on top of the semiconductor layer 15. As a result, the silicide process margin improves, thus allowing to manufacture a stable semiconductor device 2 with minimal variation. Further, if the semiconductor layer 15 grows to cover the insulating film 41, a short circuit between the silicide layer 16 and semiconductor substrate 11 can be more positively prevented.

In the aforementioned first example (including the modification example), it is important that the portion of the semiconductor layer 15 to be epitaxially grown in contact with the opening portion 42 should be grown thicker than the insulating film 41 to prevent a short circuit between the silicide layer 16 and semiconductor substrate 11.

An embodiment (second example) according to the semiconductor device of the present invention will be described next with reference to the schematic configurational sectional diagram of FIG. 3.

As illustrated in FIG. 3, the element forming region 12 is isolated by the element isolating region 14 formed in the semiconductor substrate 11. The semiconductor substrate 11 includes, for example, a silicon substrate. On the other hand, the element isolating region 14 is formed by a technique such as LOCOS (Local Oxidation of Silicon), STI (Shallow Trench Isolation) or DTI (Deep Trench Isolation).

The insulating film 41 is formed on the semiconductor substrate 11. The insulating film 41 serves as a mask for selective epitaxial growth in a subsequent process. The same film 41 is formed, for example, with a silicon nitride film to a thickness of 20 nm. In the same film 41, the opening portion 42 is formed to include the region to be selectively epitaxially grown in the element forming region 12. In this example, the opening portion 42 is formed to lie over the element forming region 12. That is, the same portion 42 is formed narrower than the element forming region 12.

Then, the semiconductor layer 15 is formed by selective epitaxial growth of the element forming region 12 of the semiconductor substrate 11 in the opening portion 42. The semiconductor layer 15 should be preferably formed, for example, thicker than the insulating film 41 in the opening portion 42. Further, the semiconductor layer 15 should be preferably formed to cover part of the insulating film 41.

A second semiconductor layer 17 is formed on the semiconductor layer 15. The second semiconductor layer 17 is isolated from the semiconductor substrate 11 by the insulating film 41.

The semiconductor device configured as described above is surrounded by the insulating film 41 in which the opening portion 42 is formed to include the region to be selectively epitaxially grown. As a result, the semiconductor layer 15 which is formed by selective epitaxial growth of the element forming region 12 of the semiconductor substrate 11 in the opening portion 42 also grows along the sidewall of the opening portion 42. This distances the top surface of the semiconductor layer 15 more from the semiconductor substrate 11 by the thickness of the same layer 15 grown. This prevents a short circuit between the second semiconductor layer 17 and semiconductor substrate 11 even if the second semiconductor layer 17 is formed on top of the semiconductor layer 15. As a result, the process margin improves, thus allowing to manufacture a stable semiconductor device 3 with minimal variation. Further, if the semiconductor layer 15 grows to cover the insulating film 41, a short circuit between the second semiconductor layer 17 and semiconductor substrate 11 can be more positively prevented.

An embodiment (second example) according to the semiconductor device manufacturing method of the present invention will be described next with reference to the aforementioned FIG. 3.

For example, the semiconductor substrate 11 is made available. A silicon substrate, for example, is used as the semiconductor substrate 11. The element isolating region 14 is formed in the semiconductor substrate 11 to isolate the element forming region 12. The element isolating region 14 is formed by a technique such as LOCOS (Local Oxidation of Silicon), STI (Shallow Trench Isolation) or DTI (Deep Trench Isolation).

Next, the insulating film 41 is formed on the semiconductor substrate 11. The insulating film 41 serves as a mask for selective epitaxial growth in a subsequent process. The same film 41 is formed, for example, with a silicon nitride film to a thickness of 20 nm. Next, typical resist coating is performed, followed by the formation of an etching mask (not shown) by a lithography technique. The mask has an opening in the region to be selectively epitaxially grown of the element forming region 12. Then, the opening portion 42 is formed in the insulating film 41 on the region to be selectively epitaxially grown of the element forming region 12 by the etching process using the etching mask. Here, the region to be selectively epitaxially grown is the element forming region 12 in the opening portion 42.

Next, the semiconductor layer 15 is formed on the element forming region 12 in the opening portion 42 by selective epitaxial growth. If the semiconductor layer 15 is doped, for example, into a p-type semiconductor layer, diborane (B₂H₆) gas is used as a dopant source gas together with a silane-based gas. On the other hand, if the semiconductor layer 15 is doped into an n-type semiconductor layer, arsine (AsH₃), phosphine (PH₃) or other gas is used, for example, as a dopant source gas together with a silane-based gas. Further, the surface of the semiconductor substrate 11 may be cleaned as necessary prior to epitaxial growth with a chemical solution such as HF or hydrogen (H₂) gas.

The second semiconductor layer 17 is formed successively on the semiconductor layer 15 by selective epitaxial growth. If the second semiconductor layer 17 is doped, for example, into a p-type semiconductor layer, diborane (B₂H₆) gas is used as a dopant source gas together with a silane-based gas. On the other hand, if the second semiconductor layer 17 is doped into an n-type semiconductor layer, arsine (AsH₃), phosphine (PH₃) or other gas is used, for example, as a dopant source gas together with a silane-based gas.

In the aforementioned semiconductor device manufacturing method, the opening portion 42 is formed in the insulating film 41 to include the region to be selectively epitaxially grown. As a result, the semiconductor layer 15 which is formed by selective epitaxial growth of the element forming region 12 of the semiconductor substrate 11 in the opening portion 42 also grows along the sidewall of the opening portion 42. This distances the top surface of the semiconductor layer 15 more from the semiconductor substrate 11 by the thickness of the same layer 15 grown. This prevents a short circuit between the second semiconductor layer 17 and semiconductor substrate 11 even if the second semiconductor layer 17 is formed on top of the semiconductor layer 15. As a result, the process margin improves, thus allowing to manufacture the stable semiconductor device 3 with minimal variation. Further, if the semiconductor layer 15 grows to cover the insulating film 41, a short circuit between the second semiconductor layer 17 and semiconductor substrate 11 can be more positively prevented.

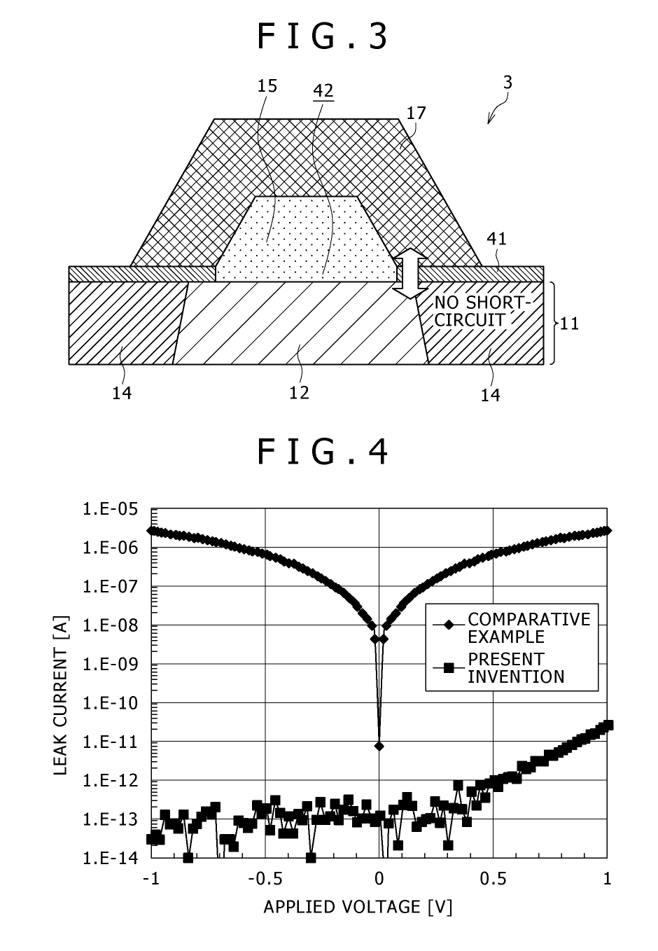

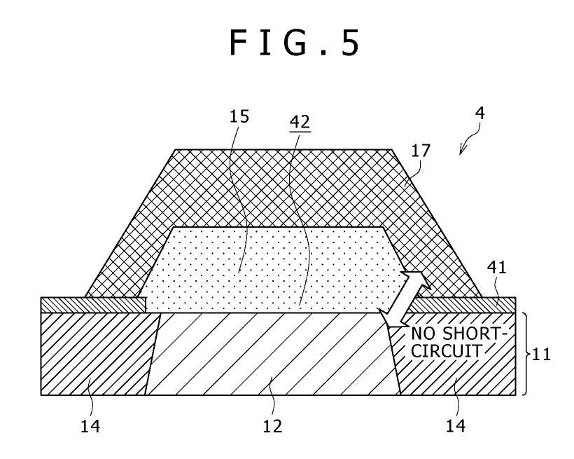

Next, the leakage current characteristic of the semiconductor device 3 configured as described above was investigated. A voltage was applied to the second semiconductor layer 17 with the semiconductor substrate 11 serving as a ground. The relationship between the leakage current and applied voltage found from the investigation are shown in FIG. 4. The comparative example in FIG. 4 illustrates the case in which the semiconductor layer 15 and second semiconductor layer 17 were epitaxially grown directly on the element forming region 12 of the semiconductor substrate 11 without forming the insulating film 41.

As illustrated in FIG. 4, the larger the absolute value of the applied voltage, the greater the leakage current in the comparative example. It is clear, however, that an extremely small or almost no leakage current flows in the semiconductor device 3 according to the second example of the present invention as compared to the comparative example. It should be noted that the insulating film 41 of the semiconductor device 3 was formed with a silicon nitride film of 20 nm in thickness.

A modification example of the aforementioned second example will be described next with reference to the schematic configurational sectional diagram of FIG. 5.

As illustrated in FIG. 5, the element forming region 12 is isolated by the element isolating region 14 formed in the semiconductor substrate 11. The semiconductor substrate 11 includes, for example, a silicon substrate. On the other hand, the element isolating region 14 is formed by a technique such as LOCOS (Local Oxidation of Silicon), STI (Shallow Trench Isolation) or DTI (Deep Trench Isolation).

The insulating film 41 is formed on the semiconductor substrate 11. The insulating film 41 serves as a mask for selective epitaxial growth in a subsequent process. The same film 41 is formed, for example, with a silicon nitride film to a thickness of 20 nm. In the same film 41, the opening portion 42 is formed to include the region to be selectively epitaxially grown in the element forming region 12. In this example, the opening portion 42 is formed to lie over the element isolating region 14. That is, the same portion 42 is formed wider than the element forming region 12.

Then, the semiconductor layer 15 is formed by selective epitaxial growth of the element forming region 12 of the semiconductor substrate 11 in the opening portion 42. The semiconductor layer 15 is preferably formed, for example, thicker than the insulating film 41 in the opening portion 42. Further, the semiconductor layer 15 may be formed to cover part of the insulating film 41.

The second semiconductor layer 17 is formed successively on the semiconductor layer 15 by selective epitaxial growth. If the second semiconductor layer 17 is doped, for example, into a p-type semiconductor layer, diborane (B₂H₆) gas is used as a dopant source gas together with a silane-based gas. On the other hand, if the second semiconductor layer 17 is doped into an n-type semiconductor layer, arsine (AsH₃), phosphine (PH₃) or other gas is used, for example, as a dopant source gas together with a silane-based gas.

The semiconductor device configured as described above is surrounded by the insulating film 41 in which the opening portion 42 is formed to include the region to be selectively epitaxially grown. Further, the epitaxial growth also takes place horizontally. Therefore, the semiconductor layer 15 which is formed by selective epitaxial growth of the element forming region 12 of the semiconductor substrate 11 in the opening portion 42 also grows in contact with the sidewall of the opening portion 42. This distances the top surface of the semiconductor layer 15 more from the semiconductor substrate 11 by the thickness of the same layer 15 grown. This prevents a short circuit between the second semiconductor layer 17 and semiconductor substrate 11 even if the second semiconductor layer 17 is formed on top of the semiconductor layer 15. As a result, the process margin improves, thus allowing to manufacture a stable semiconductor device 4 with minimal variation. Further, if the semiconductor layer 15 grows to cover part of the insulating film 41, a short circuit between the second semiconductor layer 17 and semiconductor substrate 11 can be more positively prevented.

In the aforementioned second example (including the modification example), it is important that the portion of the semiconductor layer 15 to be epitaxially grown in contact with the opening portion 42 should be grown thicker than the insulating film 41 to prevent a short circuit between the second semiconductor layer 17 and semiconductor substrate 11.

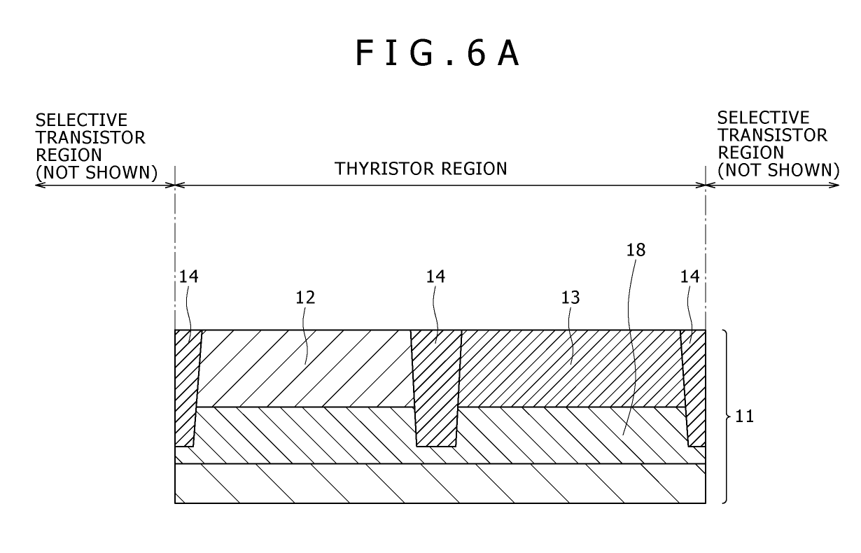

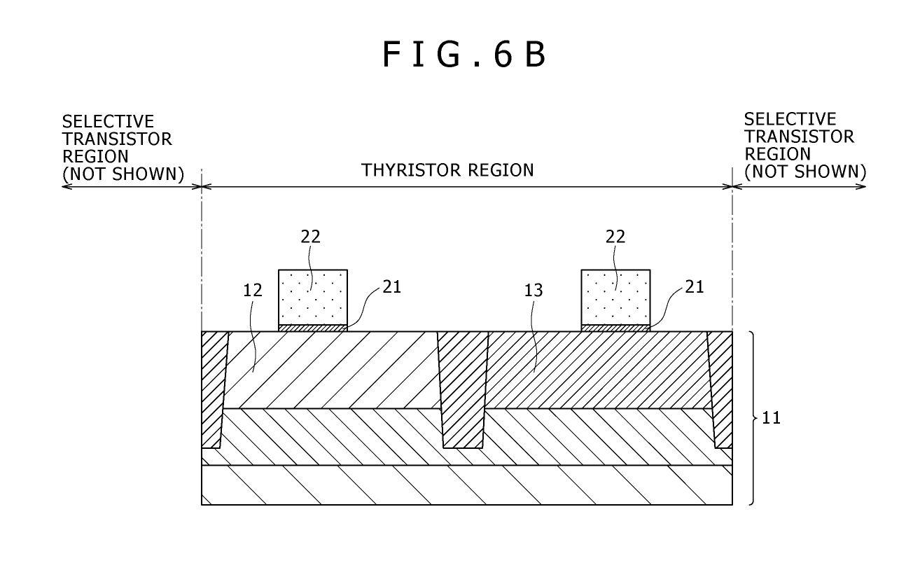

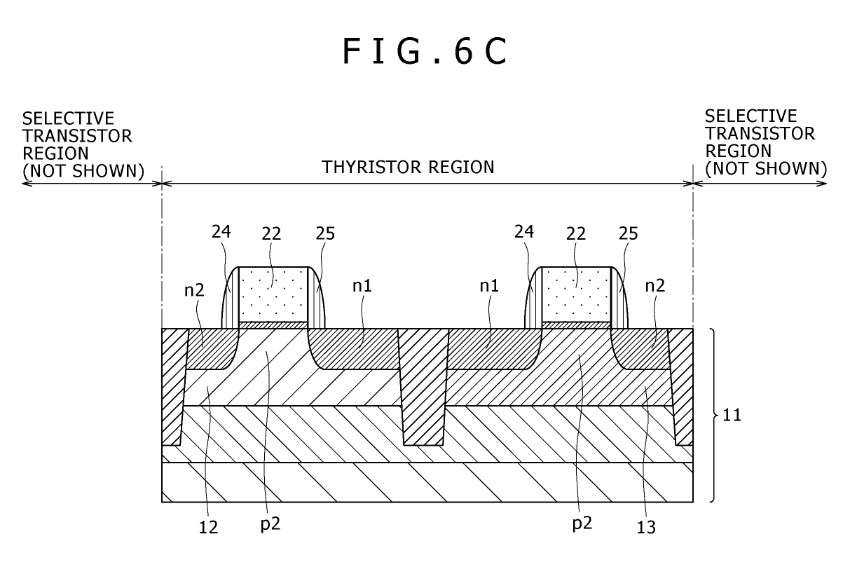

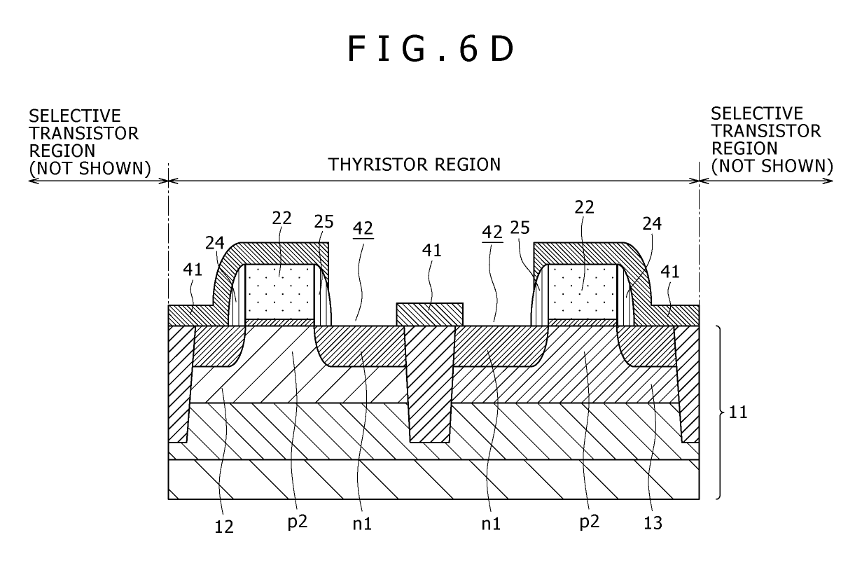

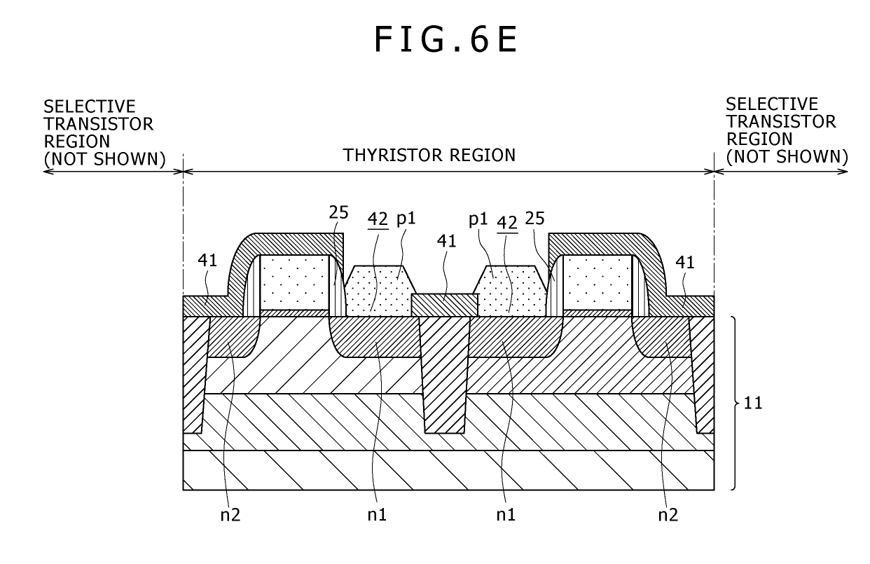

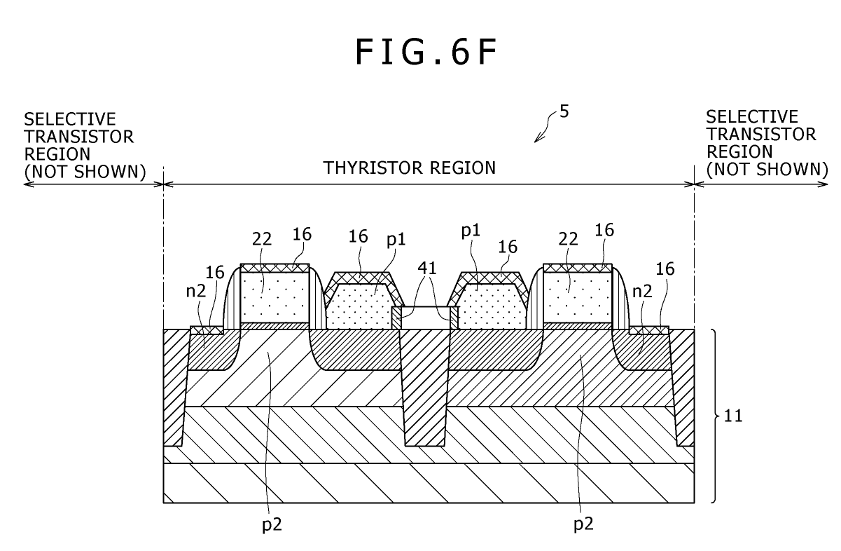

A description will be given next of the first example of the embodiment with reference to the sectional manufacturing process diagrams in FIGS. 6A to 6F. In this example, the semiconductor device and manufacturing method of the same of the present invention are applied to a thyristor RAM. FIGS. 6S to 6F illustrate, as an example, a manufacturing method for forming two thyristors, one on each side of the element isolating region.

As illustrated in FIG. 6A, the semiconductor substrate 11 is made available. A silicon substrate, for example, is used as the semiconductor substrate 11. The element isolating region 14 is formed in the semiconductor substrate 11 to isolate the element forming region 12 and an element forming region 13 from each other. The element isolating region 14 is formed by a technique such as LOCOS (Local Oxidation of Silicon), STI (Shallow Trench Isolation) or DTI (Deep Trench Isolation). An n-well region 18, for example, is formed underneath the element forming region 12. Thereafter, the top portions of the element forming regions 12 and 13 of the semiconductor substrate 11 are formed into first conduction type (p-type) regions. These p-type regions will serve as the second p-type regions p2 (third region) of the thyristors. As examples of the ion injection conditions, it is preferred that boron, a p-type dopant, should be used as a dopant, and that the concentration thereof should be, for example, 1×10¹⁸ cm⁻³ and fall roughly in the range from 1×10¹⁷ cm⁻³ to 1×10¹⁹ cm⁻³. Basically, the dopant concentration for this region must be lower than that for the first n-type region of the second conduction type (n-type) which will be formed later. On the other hand, indium (In) or other p-type dopant can be used as the aforementioned p-type dopant in addition to boron (B).

Next, a gate insulating film 21 is formed on the semiconductor substrate 11 as illustrated in FIG. 6B. The gate insulating film 21 is formed, for example, with a silicon oxide (SiO₂) film to a thickness of about 1 to 10 nm. It should be noted that the material of the gate insulating film 21 is not limited to silicon oxide (SiO₂). In addition to silicon nitride oxide (SiON), other gate insulating film materials considered in a typical CMOS process can also be used, including hafnium oxide (HfO₂), hafnium nitride oxide (HfON), aluminum oxide (Al₂O₃), hafnium silicate (HfSiO), hafnium nitride silicate (HfSiON) and lanthanum oxide (La₂O₃).

Next, a gate electrode 22 is formed on the gate insulating film 21 which is formed on each of the element forming regions 12 and 13. The gate electrode 22 is typically formed with polycrystalline silicon. Alternatively, the same electrode 22 may be formed with a metal gate electrode. Further alternatively, the same electrode 22 may be formed with silicon germanium (SiGe) or other material.

Each of the gate electrodes 22 is formed, for example, as follows. That is, a gate electrode forming film is formed on the gate insulating film 21, followed by typical resist coating. Then, an etching mask is formed by a lithography technique. Finally, the gate electrode forming film is etched by an etching technique using the etching mask. A typical dry etching technique can be used as this etching technique. Alternatively, the gate electrodes 22 can be formed by a wet etching technique. Still alternatively, a silicon oxide (SiO₂) film or silicon nitride (Si₃N₄) film, for example, may be formed on the gate electrode forming film as a hard mask.

Next, as illustrated in FIG. 6C, sidewalls 24 and 25 are formed on the sides of each of the gate electrodes 22. For example, a sidewall forming film is formed first to coat each of the gate electrodes 22 first, followed by etching-back of the sidewall forming film to form the sidewalls 24 and 25. The sidewalls 24 and 25 may be formed with silicon oxide (SiO₂) or silicon nitride (Si₃N₄). Alternatively, the sidewalls 24 and 25 may be formed by stacking silicon oxide and silicon nitride films one on top of another.

Next, typical resist coating is performed, followed by the formation of an ion injection mask (not shown) by a lithography technique. The mask has an opening in each of the element forming regions 12 and 13 between the gate electrodes 22. Next, an n-type dopant is introduced into the semiconductor substrate 11 between the gate electrodes 22 by an ion injection technique using the ion injection mask to form the first n-type region n1 (second region) in each of the element forming regions 12 and 13. As the ion injection conditions, phosphorus (P) is used, for example, as a dopant, and the concentration thereof is set, for example, to 1.5×10¹⁹ cm⁻³. This concentration should preferably fall roughly in the range from 1×10¹⁸ cm⁻³ to 1×10²⁰ cm⁻³. However, the concentration must be higher than that for the second p-type region p2. Further, an n-type dopant such as arsenic or antimony may be used in place of phosphorus. Thereafter, the ion injection mask is removed.

Next, the semiconductor substrate is heated, for example, to 1,050° C. for activation annealing, followed immediately by a spike annealing as a cooling process. This activation annealing need only be performed under those conditions which allow for activation of the dopant.

Further, the sidewalls 24 and 25 may be formed following the ion injection adapted to form the first n-type region.

Next, typical resist coating is performed, followed by the formation of an ion injection mask (not shown) by a lithography technique. The mask has an opening on the other side of each of the gate electrodes 22, i.e., in the region where the second n-type region is formed. Next, an n-type dopant is introduced into the semiconductor substrate 11 on the other side of each of the gate electrodes 22 by an ion injection technique using the ion injection mask to form the second n-type region n2 (fourth region). As the ion injection conditions, phosphorus (P) is used, for example, as a dopant, and the concentration thereof is set, for example, to 5×10²⁰ cm⁻³. This concentration should preferably fall roughly in the range from 1×10¹⁹ cm⁻³ to 1×10²⁰ cm⁻³. However, the concentration must be higher than that for the second p-type region p2. It is important that the second n-type region n2 should function as a cathode electrode. Further, an n-type dopant such as arsenic or antimony may be used in place of phosphorus. Thereafter, the ion injection mask is removed.

Next, the semiconductor substrate is heated, for example, to 1,050° C. for activation annealing, followed immediately by a spike annealing as a cooling process. This activation annealing need only be performed under those conditions which allow for activation of the dopant.

It should be noted that the first and second n-type regions n1 and n2 may be formed in a different order from the above. The second n-type region n2 may be formed first followed by the first n-type region n1. The aforementioned annealing may be performed by a single step following the formation of the first and second n-type regions n1 and n2. Alternatively, the annealing may be performed to serve also as the activation annealing process for the source and drain of the selective transistor.

Next, as illustrated in FIG. 6D, the insulating film 41 is formed to coat the gate electrodes 22 and sidewalls 24 and 25 and so on. The insulating film 41 serves as a mask for selective epitaxial growth in a subsequent process. The same film 41 is formed, for example, with a silicon nitride film to a thickness of 20 nm. Next, typical resist coating is performed, followed by the formation of an etching mask (not shown) by a lithography technique. The mask has an opening in each of the element forming regions 12 and 13 between the gate electrodes 22. Thereafter, the opening portions 42 are formed in the insulating film 41 on each of the first n-type regions n1 by the etching process using the etching mask. This leaves the insulating film 41 in the element isolating region 14 between the gate electrodes 22. As a result of the etching process, the surface of the semiconductor substrate 11 (first n-type region n1) is exposed only in the portion to be selectively epitaxially grown. Here, a silicon nitride film is used, as an example, as the insulating film 41. This is done to provide selectivity during epitaxial growth. Therefore, other types of insulating films may also be used so long as the selectivity can be maintained. Thereafter, the etching mask is removed. Further, this process may be performed simultaneously with the formation of the sidewalls 24 and 25. On the other hand, the film is set thinner than the epitaxial film of the first p-type region p1 to be grown next.

Further, in the process adapted to expose the surface of the semiconductor substrate 11 (first n-type region n1), the silicon nitride film having selectivity is opened in each of the element forming regions 12 and 13 which are active regions. In the present invention, the insulating film 41 left in the element isolating region 14 may cover part of the element forming regions 12 and 13 which are active regions. Alternatively, even if the insulating film 41 does not cover part of the active element forming regions 12 and 13, the silicon nitride film may be opened so that the sidewalls 24 and 25 having selectivity to epitaxial growth come in contact with a selectively epitaxially grown layer to be formed in the next process. That is, it is important that an insulating film should be formed around the first n-type region n1 to be selectively epitaxially grown.

Next, the first p-type region p1 (first region) of the first conduction type (p-type) is formed in the opening portion 42 on each of the first n-type regions n1 as illustrated in FIG. 6E. The first p-type regions p1 are formed, for example, by selective epitaxial growth. The boron (B) concentration in the film was 1×10²⁰ cm⁻³. As the selective epitaxial growth conditions at this time, diborane (B₂H₆) was used, for example, as a dopant source gas together with a silane-based gas. The substrate temperature during the film formation was set, for example, to 750° C. The film thickness was set, for example, to 200 nm by adjusting the dopant source gas supply, pressure of the film forming atmosphere and other factors. The dopant (boron) concentration should preferably fall roughly in the range from 1×10¹⁸ cm⁻³ to 1×10²¹ cm⁻³. On the other hand, the film thickness should preferably fall roughly in the range from 50 nm to 300 nm. However, the first p-type region p1 may have a desired thickness so long as this region functions as an anode electrode. Further, the surface of the semiconductor substrate 11 may be cleaned at this time as necessary with a chemical solution such as HF or hydrogen (H₂) gas.

In the above example, the second n-type region n2 was formed by an ion injection technique. However, the same region may be formed by the selective epitaxial growth technique according to an embodiment of the present invention. In that case, a silicon nitride film is deposited to a thickness of 20 nm again following the above process. Then, the region which will serve as the second n-type region n2 is opened by patterning with a resist, followed by the etching of the silicon nitride film.

Here, a silicon nitride film was used as an example. However, this was done to provide selectivity during epitaxial growth. Therefore, other types of films and films of different thicknesses may also be used so long as the selectivity can be maintained.

Next, the second n-type region n2 is formed by selective epitaxial growth. As the selective epitaxial growth conditions at this time, arsine (AsH₃) gas was used, for example, as a dopant source gas together with a silane-based gas. The substrate temperature during the film formation was set, for example, to 750° C. The film thickness was set, for example, to 200 nm by adjusting the dopant source gas supply, pressure of the film forming atmosphere and other factors. The dopant (arsenic) concentration should preferably fall roughly in the range from 1×10¹⁸ cm⁻³ to 1×10²¹ cm⁻³. Here, the concentration was set to 1×10²⁰ cm⁻³ as an example. On the other hand, the film thickness should preferably fall roughly in the range from 50 nm to 300 nm. However, the second n-type region n2 may have a desired thickness so long as this region functions as a cathode electrode. Naturally, a gas such as phosphine (PH₃) or organic source may be used so long as it can dope the region with an n-type impurity.

Further, the first p-type region p1 was formed first, followed by the second n-type region n2 in the above example. However, the second n-type region n2 may be formed first, followed by the first p-type region p1. Still further, the silicon (Si) substrate surface may be cleaned at this time as necessary with a chemical solution such as hydrofluoric acid (HF) or hydrogen (H₂) gas. Still further, either or both of the first p-type region p1 and second n-type region n2 may be subjected to activation annealing as necessary following their formation. As an activation annealing, the substrate is heated, for example, to 1,000° C. for activation annealing, followed immediately by a spike annealing as a cooling process. This activation annealing need only be performed under those conditions which allow for activation of the dopant.

Next, the insulating film 41 (refer to FIG. 6D) is removed to expose the gate electrodes 22, first p-type regions p1 and second n-type regions n2. It should be noted that if the second n-type regions n2 are formed by selective epitaxial growth, the silicon nitride film used for that purpose is also removed. At this time, the insulating film 41 under the portion of the first p-type region p1 which sticks out like a visor, i.e., under the first p-type region p1 formed to cover the insulating film 41, is left unremoved. This unremoved insulating film 41 prevents a short circuit between the silicide layer 16, which will be formed later, and semiconductor substrate 11. Then, prior to the formation of an interlayer insulating film (not shown), the silicide layer 16 is formed, for example, with titanium silicide, cobalt silicide or nickel silicide by a silicide process. The silicide layer 16 is formed on each of the exposed regions, i.e., the first p-type regions p1, second n-type regions n2 and gate electrodes 22. Thereafter, the interlayer insulating film is formed, followed by a wiring process similar to a typical CMOS process.

As described above, a semiconductor device 5 according to the first example of the present invention has a thyristor structure. In this structure, the first p-type region p1 (first region) of the first conduction type (e.g., p-type), first n-type region n1 (second region) of the second conduction type (e.g., n-type) opposite to the first conduction type, second p-type region p2 (third region) of the first conduction type (p-type) and second n-type region n2 (fourth region) of the second conduction type (n-type) are joined together in succession. The semiconductor device 5 is configured so that the first p-type region p1 is formed by epitaxial growth of the element forming regions 12 and 13 in the opening portion 42 formed in the insulating film 41. In the figure, part of the opening portion 42 is shown to lie under the sidewalls 24 and 25. However, this will not cause any problems because the sidewalls 24 and 25 are formed with a silicon oxide or silicon nitride film. This allows the sidewalls 24 and 25 to function as masks for selective epitaxial growth. The semiconductor device 5 is also configured so that a short circuit between the silicide layer 16 and semiconductor substrate 11 is prevented because of the isolation of the silicide layer 16 from the semiconductor substrate 11 by the insulating film 41 and sidewalls 24 and 25.

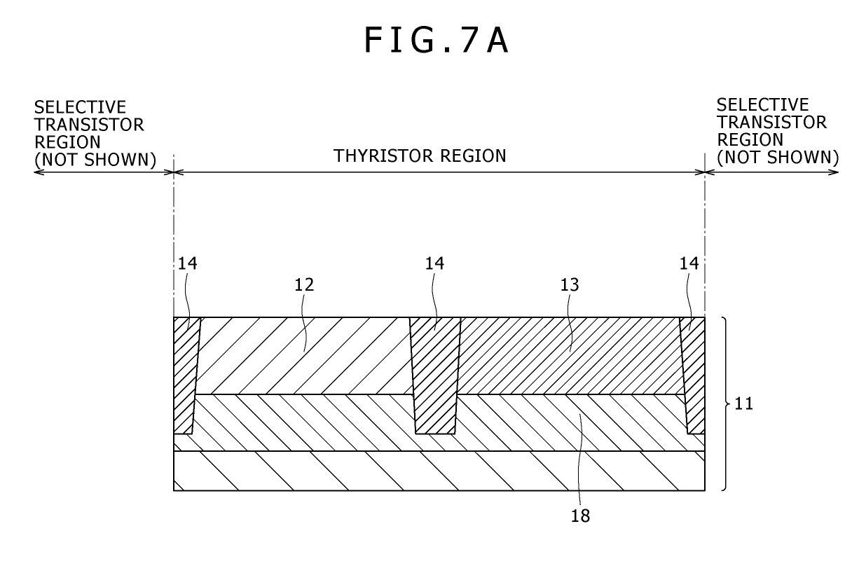

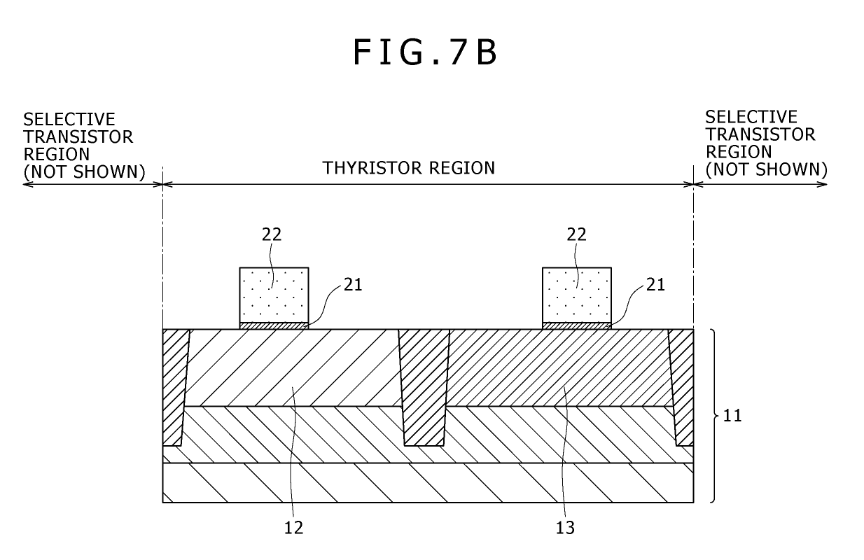

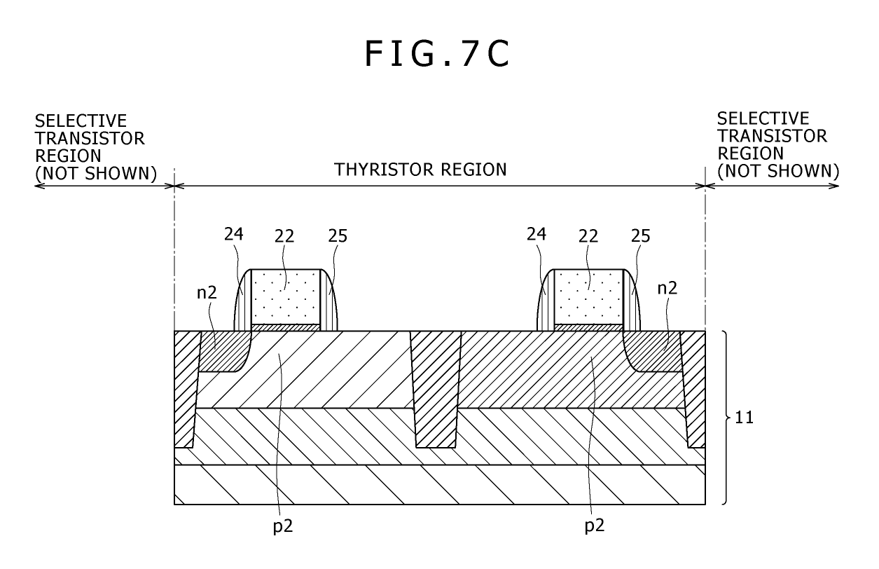

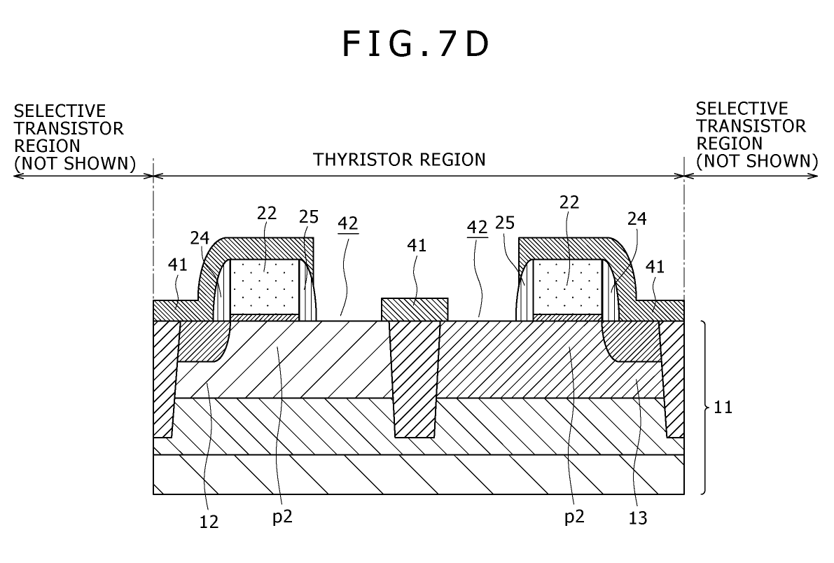

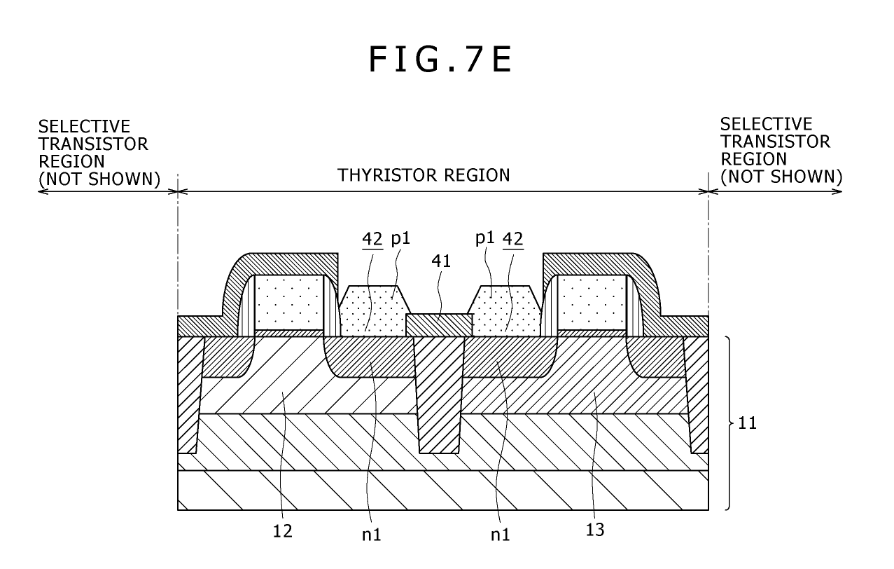

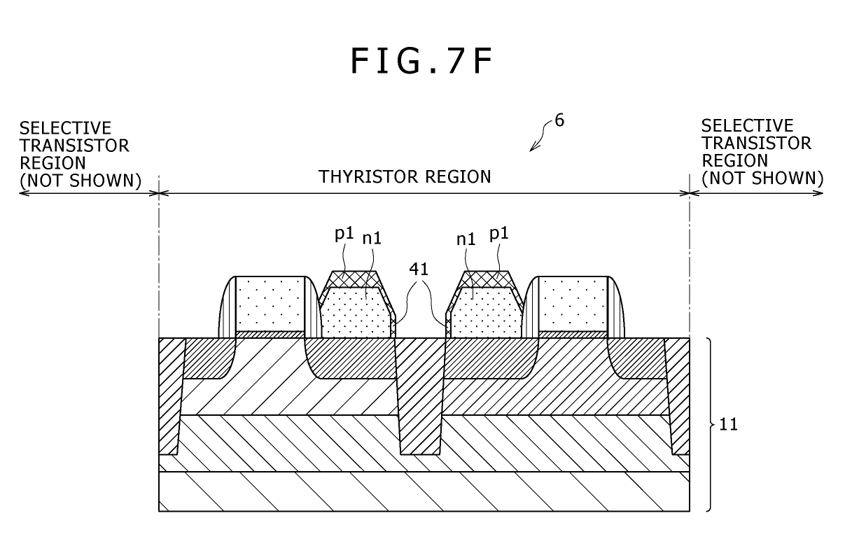

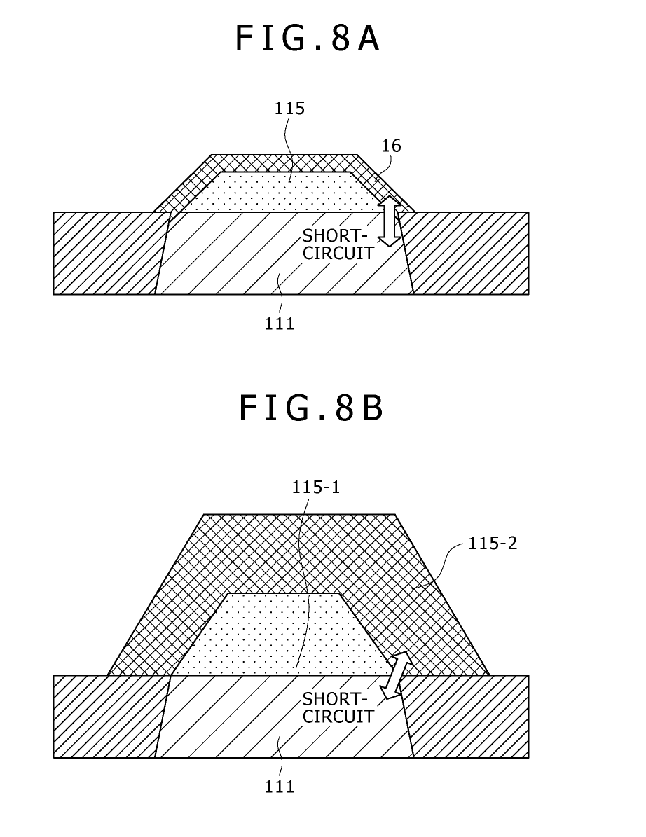

A description will be given next of the second example of the embodiment with reference to the sectional manufacturing process diagrams in FIGS. 7A to 7F. In this example, the semiconductor device and manufacturing method of the same of the present invention are applied to a thyristor RAM. FIGS. 7A to 7F illustrate, as an example, a manufacturing method for forming two thyristors, one on each side of the element isolating region.

As illustrated in FIG. 7A, the semiconductor substrate 11 is made available. A silicon substrate, for example, is used as the semiconductor substrate 11. The element isolating region 14 is formed in the semiconductor substrate 11 to isolate the element forming regions 12 and 13 from each other. The element isolating region 14 is formed by a technique such as LOCOS (Local Oxidation of Silicon), STI (Shallow Trench Isolation) or DTI (Deep Trench Isolation). The n-well region 18, for example, is formed underneath the element forming region 12. Thereafter, the top portions of the element forming regions 12 and 13 of the semiconductor substrate 11 are formed into first conduction type (p-type) regions. These p-type regions will serve as the second p-type regions p2 (third region) of the thyristors. As examples of the ion injection conditions, it is preferred that boron, a p-type dopant, should be used as a dopant, and that the concentration thereof should be, for example, 1×10¹⁸ cm⁻³ and fall roughly in the range from 1×10¹⁷ cm⁻³ to 1×10¹⁹ cm⁻³. Basically, the dopant concentration for this region must be lower than that for the first n-type region of the second conduction type (n-type) which will be formed later. On the other hand, indium (In) or other p-type dopant can be used as the aforementioned p-type dopant in addition to boron (B).

Next, the gate insulating film 21 is formed on the semiconductor substrate 11 as illustrated in FIG. 7B. The gate insulating film 21 is formed, for example, with a silicon oxide (SiO₂) film to a thickness of about 1 to 10 nm. It should be noted that the material of the gate insulating film 21 is not limited to silicon oxide (SiO₂). In addition to silicon nitride oxide (SiON), other gate insulating film materials considered in a typical CMOS process can also be used, including hafnium oxide (HfO₂), hafnium nitride oxide (HfON), aluminum oxide (Al₂O₃), hafnium silicate (HfSiO), hafnium nitride silicate (HfSiON) and lanthanum oxide (La₂O₃).

Next, the gate electrode 22 is formed on the gate insulating film 21 on the region which will serve as the second p-type region p2. The gate electrode 22 is typically formed with polycrystalline silicon. Alternatively, the same electrode 22 may be formed with a metal gate electrode. Further alternatively, the same electrode 22 may be formed with silicon germanium (SiGe) or other material.

Each of the gate electrodes 22 is formed, for example, as follows. That is, a gate electrode forming film is formed on the gate insulating film 21, followed by typical resist coating. Then, an etching mask is formed by a lithography technique. Finally, the gate electrode forming film is etched by an etching technique using the etching mask. A typical dry etching technique can be used as this etching technique. Alternatively, the gate electrodes 22 can be formed by a wet etching technique. Still alternatively, a silicon oxide (SiO₂) film or silicon nitride (Si₃N₄) film, for example, may be formed on the gate electrode forming film as a hard mask.

Next, as illustrated in FIG. 7C, the sidewalls 24 and 25 are formed on the sides of each of the gate electrodes 22. For example, a sidewall forming film is formed first to coat each of the gate electrodes 22 first, followed by etching-back of the sidewall forming film to form the sidewalls 24 and 25. The sidewalls 24 and 25 may be formed with silicon oxide (SiO₂) or silicon nitride (Si₃N₄). Alternatively, the sidewalls 24 and 25 may be formed by stacking silicon oxide and silicon nitride films one on top of another.

Next, typical resist coating is performed, followed by the formation of an ion injection mask (not shown) by a lithography technique. The mask has an opening on the other side of each of the gate electrodes 22, i.e., in the region where the second n-type region is formed. Next, an n-type dopant is introduced into the semiconductor substrate 11 on the other side of each of the gate electrodes 22 by an ion injection technique using the ion injection mask to form the second n-type region n2 (fourth region). As the ion injection conditions, phosphorus (P) is used, for example, as a dopant, and the concentration thereof is set, for example, to 5×10²⁰ cm⁻³. This concentration should preferably fall roughly in the range from 1×10¹⁹ cm⁻³ to 1×10²⁰ cm⁻³. However, the concentration must be higher than that for the second p-type region p2. It is important that the second n-type region n2 should function as a cathode electrode. Further, an n-type dopant such as arsenic or antimony may be used in place of phosphorus. Thereafter, the ion injection mask is removed.

Next, the semiconductor substrate is heated, for example, to 1,050° C. for activation annealing, followed immediately by a spike annealing as a cooling process. This activation annealing need only be performed under those conditions which allow for activation of the dopant. Alternatively, the aforementioned annealing may be performed to serve also as the activation annealing process for the source and drain of the selective transistor.

Next, as illustrated in FIG. 7D, the insulating film 41 is formed to coat the gate electrodes 22 and sidewalls 24 and 25 and so on. The same film 41 is formed, for example, with a silicon nitride film to a thickness of 20 nm. Next, typical resist coating is performed, followed by the formation of an etching mask (not shown) by a lithography technique. The mask has an opening in each of the element forming regions 12 and 13 between the gate electrodes 22. Thereafter, the opening portions 42 are formed in the insulating film 41 on each of the first n-type regions n1 by the etching process using the etching mask. This leaves the insulating film 41 in the element isolating region 14 between the gate electrodes 22. As a result of the etching process, the surface of the semiconductor substrate 11 (region where the first n-type region is formed) is exposed only in the portion to be selectively epitaxially grown. Here, a silicon nitride film is used, as an example, as the insulating film 41. This is done to provide selectivity during epitaxial growth. Therefore, other types of insulating films may also be used so long as the selectivity can be maintained. Thereafter, the etching mask is removed. Further, this process may be performed simultaneously with the formation of the sidewalls 24 and 25. On the other hand, the film is set thinner than the epitaxial film of the first p-type region p1 to be grown next.

Further, in the process adapted to expose the surface of the semiconductor substrate 11 (first n-type region n1), the silicon nitride film having selectivity is opened in each of the element forming regions 12 and 13 which are active regions. In the present invention, the insulating film 41 left in the element isolating region 14 may cover part of the element forming regions 12 and 13 which are active regions. Alternatively, even if the insulating film 41 does not cover part of the active element forming regions 12 and 13, the silicon nitride film may be opened so that the sidewalls 24 and 25 having selectivity to epitaxial growth come in contact with a selectively epitaxially grown layer to be formed in the next process. That is, it is important that an insulating film should be formed around the first n-type region n1 to be selectively epitaxially grown.

Next, the first n-type region n1 (second region) of the second conduction type (n-type) is formed on each of the element forming regions 12 and 13 in the opening portion 42 as illustrated in FIG. 7E. The first n-type regions n1 are formed, for example, by selective epitaxial growth. The arsenic (As) concentration in the film was 1×10¹⁸ cm⁻³. As the selective epitaxial growth conditions at this time, arsine (AsH₃) gas was used, for example, as a dopant source gas together with a silane-based gas. The substrate temperature during the film formation was set, for example, to 750° C. The film thickness was set, for example, to 100 nm by adjusting the dopant source gas supply, pressure of the film forming atmosphere and other factors. The dopant (arsenic) concentration should preferably fall roughly in the range from 1×10¹⁷ cm⁻³ to 1×10²⁰ cm⁻³. On the other hand, the film thickness should preferably fall roughly in the range from 50 nm to 300 nm. A gas such as phosphine (PH₃) or organic source may be used so long as it can dope the region with an n-type impurity. Further, the surface of the semiconductor substrate 11 may be cleaned at this time as necessary with a chemical solution such as HF or hydrogen (H₂) gas.

The first p-type region p1 (first region) is formed successively on each of the first n-type regions n1 by selective epitaxial growth as illustrated in FIG. 7F. The boron (B) concentration in the film was 1×10²⁰ cm⁻³ for the first p-type region p1. As the selective epitaxial growth conditions at this time, diborane (B₂H₆) was used, for example, as a dopant source gas together with a silane-based gas. The substrate temperature during the film formation was set, for example, to 750° C. The film thickness was set, for example, to 200 nm by adjusting the dopant source gas supply, pressure of the film forming atmosphere and other factors. The dopant (boron) concentration should preferably fall roughly in the range from 1×10¹⁸ cm⁻³ to 1×10²¹ cm⁻³. On the other hand, the film thickness should preferably fall roughly in the range from 50 nm to 300 nm. However, the first p-type region p1 may have a desired thickness so long as this region functions as an anode electrode. The unremoved insulating film 41 prevents a short circuit between the first p-type region p1 and semiconductor substrate 11.

In the above second example, the second n-type region n2 was formed by an ion injection technique. However, the same region may be formed by the selective epitaxial growth technique according to another embodiment of the present invention. In that case, a silicon nitride film is deposited to a thickness of 20 nm again following the above process. Then, the region which will serve as the second n-type region n2 is opened by patterning with a resist, followed by the etching of the silicon nitride film.

Here, a silicon nitride film is used, as an example. This is done to provide selectivity during epitaxial growth. Therefore, other types of insulating films may also be used so long as the selectivity can be maintained.

Next, the second n-type region n2 is grown by selective epitaxial growth. As the selective epitaxial growth conditions at this time, arsine (AsH₃) gas was used, for example, as a dopant source gas together with a silane-based gas. The substrate temperature during the film formation was set, for example, to 750° C. The film thickness was set, for example, to 200 nm by adjusting the dopant source gas supply, pressure of the film forming atmosphere and other factors. The dopant (arsenic) concentration should preferably fall roughly in the range from 1×10¹⁸ cm⁻³ to 1×10²¹ cm⁻³. Here, the concentration was set to 1×10²⁰ cm⁻³ as an example. On the other hand, the film thickness should preferably fall roughly in the range from 50 nm to 300 nm. However, the second n-type region n2 may have a desired thickness so long as this region functions as a cathode electrode. A gas such as phosphine (PH₃) or organic source may be used so long as it can dope the region with an n-type impurity.

As described above, a semiconductor device 6 according to the second example of the present invention has a thyristor structure. In this structure, the first p-type region p1 (first region) of the first conduction type (e.g., p-type), first n-type region n1 (second region) of the second conduction type (e.g., n-type) opposite to the first conduction type, second p-type region p2 (third region) of the first conduction type (p-type) and second n-type region n2 (fourth region) of the second conduction type (n-type) are joined together in succession. The semiconductor device 6 is configured such that the first p-type region p1 is formed by epitaxial growth of the element forming regions 12 and 13 in the opening portion 42 formed in the insulating film 41. In the figure, part of the opening portion 42 is shown to lie under the sidewalls 24 and 25. However, this will not cause any problems because the sidewalls 24 and 25 are formed with a silicon oxide or silicon nitride film. This allows the sidewalls 24 and 25 to function as masks for selective epitaxial growth. The semiconductor device 6 is also configured such that a short circuit between the second semiconductor layer 17 and semiconductor substrate 11 is prevented because of the isolation of the second semiconductor layer 17 from the semiconductor substrate 11 by the insulating film 41 and sidewalls 24 and 25.

Further, the first p-type region p1 was formed first, followed by the second n-type region n2 in the above second example. However, the second n-type region n2 may be formed first, followed by the first p-type region p1. Still further, the silicon (Si) substrate surface may be cleaned at this time as necessary with a chemical solution such as hydrofluoric acid (HF) or hydrogen (H₂) gas. Still further, either or both of the first p-type region p1 and second n-type region n2 may be subjected to activation annealing as necessary following their formation. As an activation annealing, the substrate is heated, for example, to 1,000° C. for activation annealing, followed immediately by a spike annealing as a cooling process. This activation annealing need only be performed under those conditions which allow for activation of the dopant.

It should be noted that the annealing allows the n-type impurity in the first n-type region n1 to diffuse into the semiconductor substrate 11, thus forming the first n-type region n1 also in the semiconductor substrate 11.

Next, a silicide layer forming process is performed as necessary. In this process, the insulating film 41 is removed first from the gate electrodes 22, first p-type regions p1 and second n-type regions n2 so as to expose these regions. It should be noted that if the second n-type regions n2 are formed by selective epitaxial growth, the silicon nitride film used for that purpose is also removed. At this time, the insulating film 41 under the portion of the semiconductor layer 17 which sticks out like a visor, i.e., under the semiconductor layer 17 formed to cover the insulating film 41, is left unremoved. This unremoved insulating film 41 prevents a short circuit between the silicide layer 16, which will be formed later, and semiconductor substrate 11. Then, prior to the formation of an interlayer insulating film (not shown), the silicide layer is formed, for example, with titanium silicide, cobalt silicide or nickel silicide by a silicide process. The silicide layer is formed on each of the exposed regions, i.e., the first p-type regions p1, second n-type regions n2 and gate electrodes 22. Thereafter, the interlayer insulating film is formed, followed by a wiring process similar to a typical CMOS process.

A modification example of the first and second examples will be described next.

The selective epitaxial growth in the first and second examples was accomplished by doping the target regions with an n-type or p-type impurity. However, all or some of the epitaxially grown layers may be epitaxially grown without doping, followed by the doping with a given impurity by an ion injection technique or solid layer diffusion technique.

In the first and second examples, it is assumed that a bulk silicon substrate is used as the semiconductor substrate 11. However, an SOI (Silicon on insulator) substrate may also be used.

Further, a complementary semiconductor device can be formed by changing the n-type and p-type impurities in one of the thyristors while leaving the n-type and p-type impurities in the other thyristor unchanged.

It should be understood by those skilled in the art that various modifications, combinations, sub-combinations and alterations may occur depending on design requirements and other factor in so far as they are within the scope of the appended claims or the equivalents thereof.

What is claimed is:

1. A semiconductor device comprising:
an element forming region of a semiconductor substrate isolated by an element isolating region formed in the semiconductor substrate;
an insulating film formed on the semiconductor substrate;
an opening portion formed in the insulating film to include a region to be selectively epitaxially grown in the element forming region; and
a semiconductor layer formed by selective epitaxial growth of the element forming region of the semiconductor substrate in the opening portion.

2. The semiconductor device of claim 1 comprising a thyristor, wherein
a first region of a first conduction type, second region of a second conduction type opposite to the first conduction type, third region of the first conduction type and fourth region of the second conduction type are joined together in succession to form the thyristor,
a gate of the thyristor is formed above the third region, and
the first region is formed with the semiconductor layer.

3. The semiconductor device of claim 1 comprising a thyristor, wherein
a first region of a first conduction type, second region of a second conduction type opposite to the first conduction type, third region of the first conduction type and fourth region of the second conduction type are joined together in succession to form the thyristor,
a gate of the thyristor is formed above the third region, and
the second region is formed with the semiconductor layer.

4. The semiconductor device of claim 1 comprising a thyristor, wherein
a first region of a first conduction type, second region of a second conduction type opposite to the first conduction type, third region of the first conduction type and fourth region of the second conduction type are joined together in succession to form the thyristor,
a gate of the thyristor is formed above the third region, and
the fourth region is formed with the semiconductor layer.

5. The semiconductor device of claim 1, wherein
the semiconductor layer is formed thicker than the insulating film in the opening portion.

6. The semiconductor device of claim 1, wherein
the semiconductor layer is formed to cover part of the insulating film.

7. The semiconductor device of claim 1 comprising a silicide layer formed on the semiconductor layer, wherein
the silicide layer is isolated from the semiconductor substrate by the insulating film.

8. The semiconductor device of claim 1 comprising a second semiconductor layer formed by selective epitaxial growth on the semiconductor layer, wherein
the second semiconductor layer is isolated from the semiconductor substrate by the insulating film.

9. The semiconductor device of claim 8 comprising a thyristor, wherein
a first region of a first conduction type, second region of a second conduction type opposite to the first conduction type, third region of the first conduction type and fourth region of the second conduction type are joined together in succession to form the thyristor,
a gate of the thyristor is formed above the third region,
the first region is formed with the second semiconductor layer, and
the second region is formed with the semiconductor layer.

10. A semiconductor device manufacturing method comprising the steps of:
forming an element isolating region in a semiconductor substrate to isolate an element forming region;
forming an insulating film on the semiconductor substrate;
forming an opening portion in the insulating film to include a region to be selectively epitaxially grown in the element forming region; and
forming a semiconductor layer by selective epitaxial growth of the element forming region of the semiconductor substrate in the opening portion.
